(19) United States
(12) Patent Application Publication
(10) Pub. No.: US 2013/0050963 A1
(43) Pub. Date: Feb. 28, 2013

(54) RECEPTION APPARATUS FOR CABLES AND ELECTRICAL CONNECTION DEVICE USING SAME

(71) Applicants: HAI-QING ZHOU, Shenzhen City (CN); YI-XIN TU, Shenzhen City (CN)

(72) Inventors: HAI-QING ZHOU, Shenzhen City (CN); YI-XIN TU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/237,973

(22) Filed: Sep. 21, 2011

(30) Foreign Application Priority Data
Aug. 25, 2011 (CN) 201110245728.7

(51) Int. Cl. H05K 5/00; H05K 7/02

(52) U.S. Cl. 361/752; 174/135

(57) ABSTRACT

A reception apparatus for flexible cable modules includes a plurality of holding units. Each of the holding units includes two holding bars and a holding board. The two holding bars are parallel to each other, and the two holding bars of each of the holding units are rotatably assembled with the two holding bars of a next one of the holding units to rotatably assemble all of the holding units one by one and form assemble apertures between adjacent ones of the holding board. The flexible cable modules repeatedly pass through selected ones of the assembling apertures to be held on the reception apparatus.

### BACKGROUND

1. Technical Field

The present disclosure relates to reception apparatuses for electronic components, and particularly to a reception apparatus for cables and an electrical connection device using the same.

2. Description of Related Art

Electronic devices, such as personal computers (PCs) and servers, generally include many cables. In assembly, the cables used inside the cases of the electronic devices may be difficult to arrange, and placement of the cables in the cases of the electronic devices may cause problems. When the electronic devices need to be repaired or electric connections of the electronic devices need to be changed, arrangement of the cables may make it difficult to repair the electronic devices. Furthermore, if the cables are entangled with each other, electromagnetic interference and possibly short circuits may result.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a schematic view of an electrical connection device, according to an exemplary embodiment.

FIG. 2 is similar to FIG. 1, except that an interface module of the electrical connection device is outside the electric connection device.

FIG. 3 is a schematic view of a reception apparatus as assembled in the electrical connection device and outside the electric connection device.

FIG. 4 is a schematic view of the reception apparatus detached from the electrical connection device.

FIG. 5 is an enlarged view of the part V as shown in FIG. 2.

FIG. 6 is a schematic view of part of the reception apparatus disassembled.

FIG. 7 is a schematic view of the reception apparatus assembled on and inside the electrical connection device.

### DETAILED DESCRIPTION

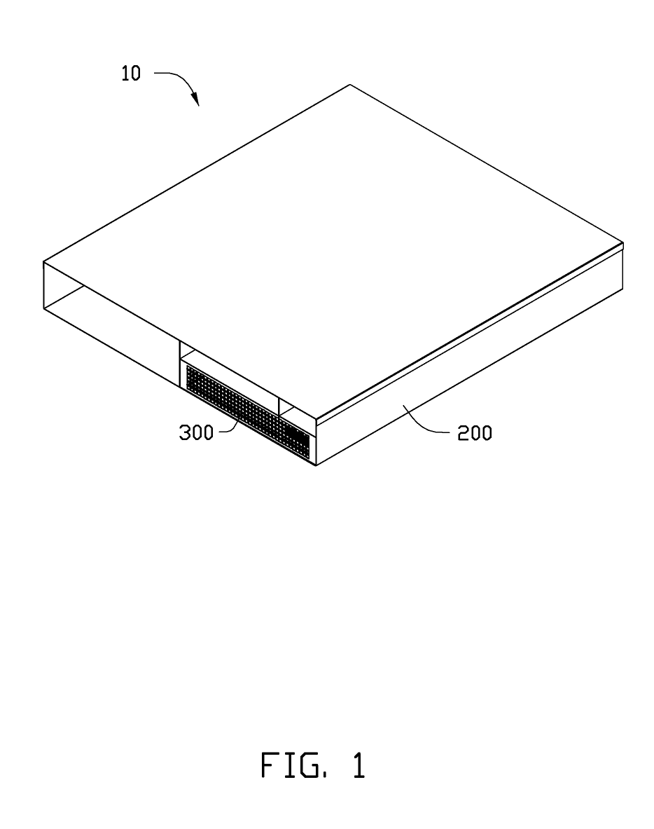

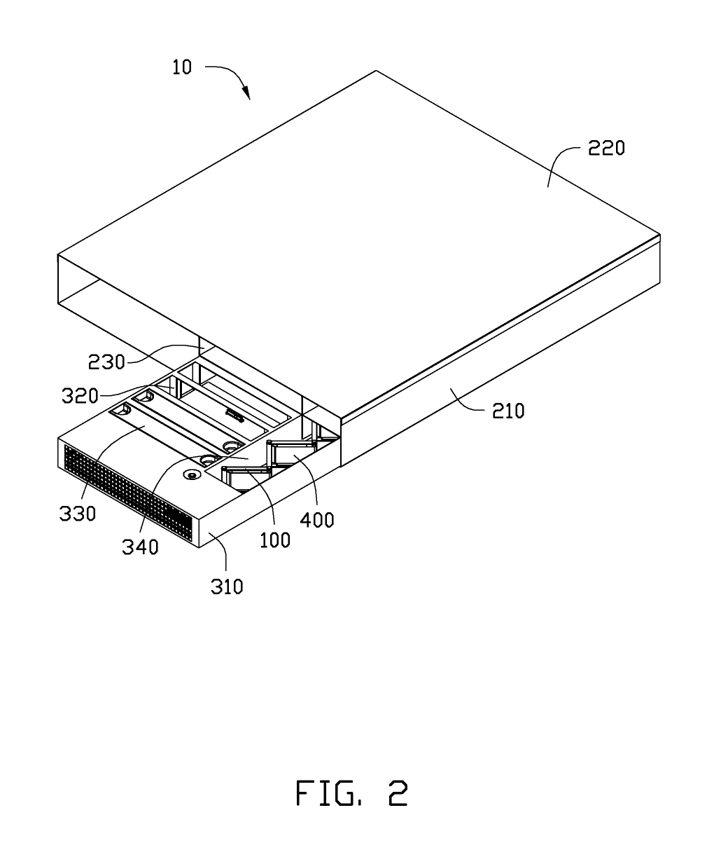

Referring to FIG. 1 and FIG. 2, an electrical connection device 10, according to an exemplary embodiment, is provided. The electrical connection device 10 can be used in many electronic devices, such as personal computers (PCs), servers, for example. The electrical connection device 10 includes a reception apparatus 100, a case 200, an interface module 300, and a flexible cable module 400. The reception apparatus 100, the interface module 300, and the flexible cable module 400 are received in the case 200 and are configured to be pulled out from the case 200. The case 200 is electrically connected to the interface 300 through the flexible cable module 400, and the reception apparatus 100 receives the flexible cable module 400.

The case 200 may be part of the housing of an electronic device. In this embodiment, the case 200 includes a substantially rectangular side frame 210 and two cover boards 220. The two cover boards 220 and the side frame 210 cooperatively form a reception space 230. The case 200 further includes a circuit board 240 and a pair of sliding rails 250. The circuit board 240 is fixed in the case 200 and can be electrically connected to the flexible cable module 400. The circuit board 240 can also be electrically connected to a number of electronic components (not shown) of the electronic device. The sliding rails 250 are formed on one of the cover boards 220.

The interface module 300 can be received inside the reception space 230, and includes a connection box 310 and a sliding box 320. Each of the connection box 310 and the sliding box 320 is substantially cuboid-shaped, and includes two opposite and parallel side surfaces and two opposite and planar ends. The sliding box 320 is mounted between the two sliding rails 250, and the two side surfaces of the sliding box 320 respectively cooperate with the two sliding rails 250 to enable a sliding movement by the sliding box 320. One of the two ends of the sliding box 320 is connected to one of the two side surfaces of the connection box 310. One of the two side surfaces of the sliding box 320 is perpendicularly connected to the side surface of the connection box 310 which is connected to the sliding box 320, and the other of the two side surfaces of the sliding box 320 is coplanar with one of the two ends of the connection box 310. A plurality of main connectors 312 are mounted on the other of the two side surfaces of the connection box 310. A retaining board 314 is also perpendicularly connected to the side surface of the connection box 310 which is connected to the sliding box 320. The retaining board 314 is coplanar with the other of the two ends of the connection box 310 and is parallel to the two side surfaces of the sliding box 320, such that a retaining groove 340 is created between the retaining board 314 and the sliding box 320.

The sliding box 320 further includes a plurality of subsidiary connectors 321 and accessories 323. The subsidiary connectors 321 are mounted inside the sliding box 320 and can be electrically connected to the main connectors 312. The sliding box 320 defines a plurality of connection apertures 322 aligned with the subsidiary connectors 321 correspondingly. The accessories 323 can be replaceable and/or exchangeable components of the electronic device, such as storage devices, sound cards, graphics cards, for example. The accessories 323 can be received in the connection apertures 322, and the subsidiary connectors 321 can be inserted in the accessories 323 when the accessories 323 are received in the connection apertures 322.

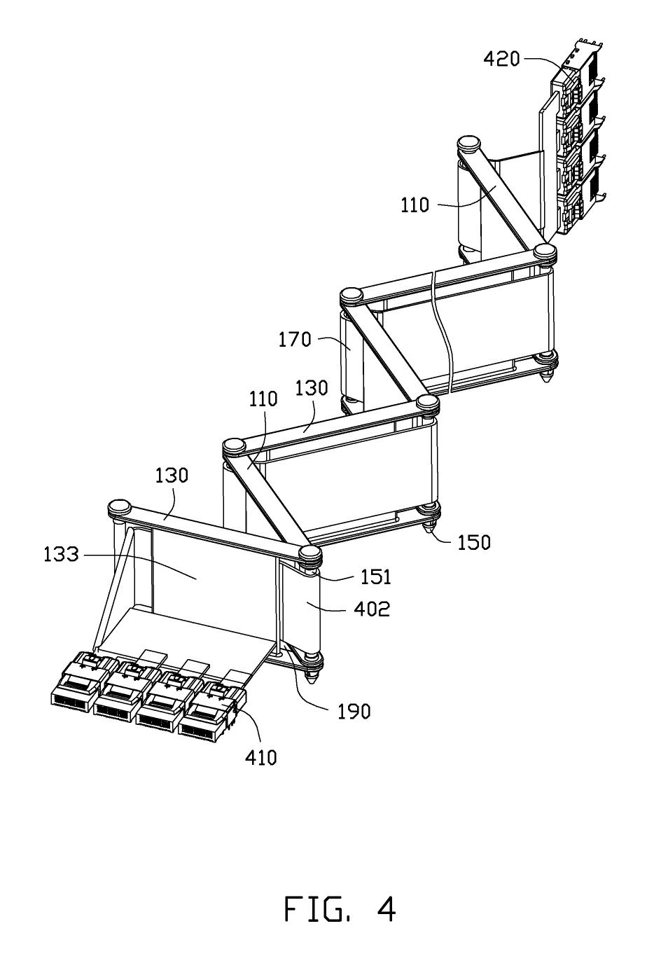

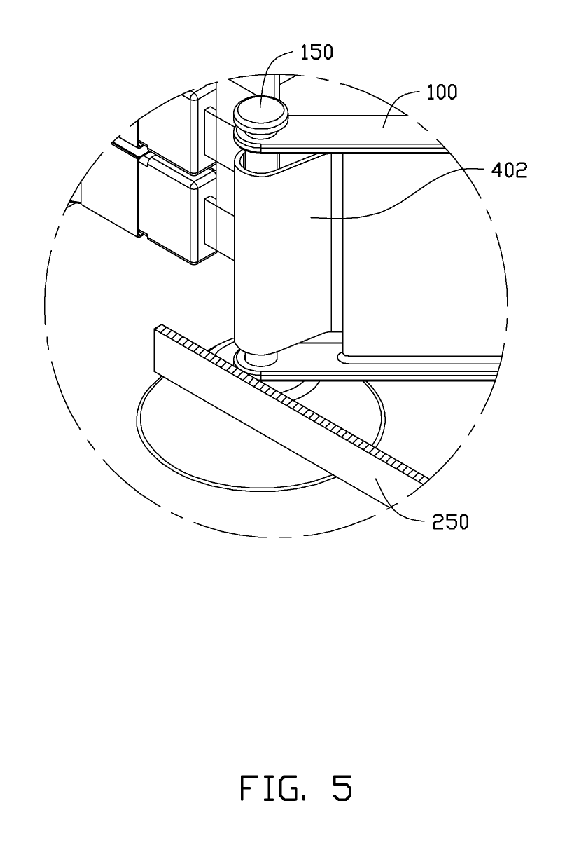

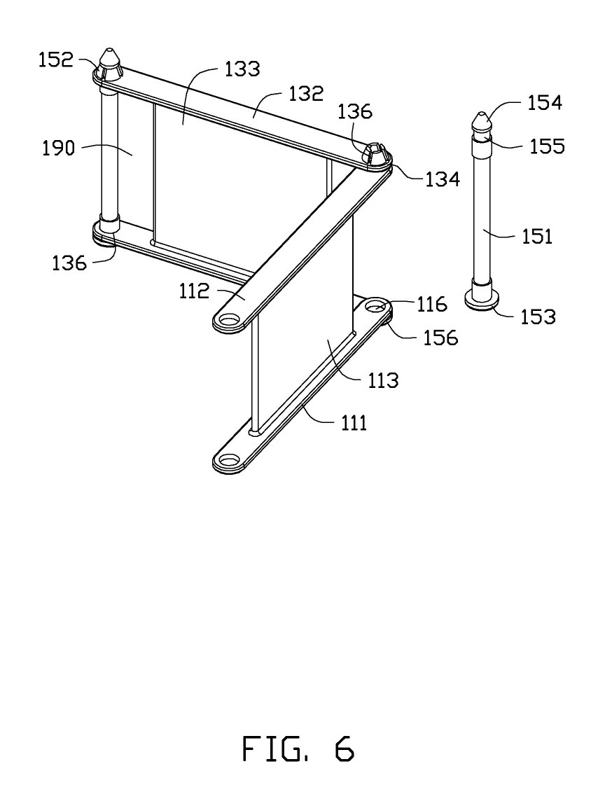

Also referring to FIGS. 4-6, the flexible cable module 400 includes a flexible cable unit 402 and a connection unit (cable connection units 410 and 420) on each end of the flexible cable unit 402. In this embodiment, the flexible cable unit 402 is a flat flexible cable (FFC), and the two cable connection units 410, 420 can be connectors appropriate for the FFC.

The reception apparatus 100 includes a plurality of first holding units 110, a plurality of second holding units 130, and a plurality of rotation units 150. Each of the first holding units 110 includes two holding bars 111, 112 and a holding board 113. The holding board 113 is a substantially rectangular flat board. The holding bars 111, 112 are all equal in length. The length of the holding board 113 is less than the length of the holding bars 111, 112, and the thickness of the holding board 113 is less than the widths of the holding bars 111, 112. The two holding bars 111, 112 are parallel to each other, and the holding board 113 holds the two holding bars 111 and 112 together lengthwise, with substantial vertical and horizontal symmetry. Each end of both the two holding bars 111, 112 defines an assembling hole 116.

Each of the second holding units 130 includes two holding bars 131, 132, and a holding board 133. All of the second holding units 130 are similar to that of the first holding units 110, except that the holding board 133 in each of the second holding units 130 has a greater lateral width, to hold the holding bars 131 and 132 farther apart. Thus, the two holding bars 111, 112 of each of the first holding units 110 can be positioned between the two holding bars 131, 132 of each of the second holding units 130, so as to align the assembling holes 116 with the assembling holes 136 in a closefitting manner.

Each of the rotation units 150 includes a shaft 151 and a limiting member 152. The shaft 151 is substantially cylindrically-shaped. The diameter of one end of the shaft 151 is stepped outwards to form a disk-shaped retaining portion 153 of a greater diameter. A conic insertion portion 154 is formed on the other end of the shaft 151, and the diameter of the part of the shaft 151 that is adjacent to the bottom of the inserting portion 154 is stepped inwards to define a limiting groove 155. The diameter of the retaining portion 153 is greater than the diameter of the assembling holes 116, and the diameter(s) of all of the other parts of the shaft 151 (i.e., including the inserting portion 154 and the part of the shaft 151 that defines the retaining groove 155) are less than the diameter of the assembling holes 116. The limiting member 152 is substantially a hollow cone made of elastic material, such as rubber. The inner diameter of the top of the limiting member 152 is less than the diameter of the bottom of the inserting portion 154, and the outer diameter of the bottom of the limiting member 152 is greater than the diameter of the assembling holes 116. Each of the rotation units 150 further includes a gasket 156. The gasket 156 can be an elastic ring. The outer diameter of the gasket 156 substantially equals the diameter of the retaining portion 153, and the inner diameter of the gasket 156 substantially equals the diameter of the part of the shaft 151 that is adjacent to the retaining portion 153.

In assembly, the first holding units 110 and the second holding units 130 are positioned alternately. In each of the first holding units 110, one end of the holding bar 111 and one end of the holding bar 112 of the first holding unit 110 are positioned between one end of the holding bar 131 and one end of the holding bar 132 of one of the second holding units 130 that is positioned adjacent to the first holding unit 110, and the assembling holes 116 are aligned with the assembling holes 136.

One of the rotation units 150 is used to assemble the first holding unit 110 and the second holding unit 130 together. In assembly, the inserting portion 154 of the rotation unit 150 is inserted into the gasket 156 of the rotation unit 150, the assembling hole 136 of the holding bar 131, the assembling hole 116 of the holding bar 111, the assembling hole 116 of the holding bar 112, and the assembling hole 136 of the holding bar 132, and is finally inserted through the bottom of the limiting member 152 of the rotation unit 150, to emerge from the top of the limiting member 152. The limiting member 152 contracts elastically into the limiting groove 155 and thereby is fixed on the shaft 151. In this way, the first holding unit 110 and the second holding unit 120 are assembled together by the rotation unit 150 and can be rotated relative to each other. The limiting member 152 and the retaining portion 153 prevent the shaft 151 from sliding out of the assembling holes 116, 136. The limiting member 152 can decrease the effect of shocks between the inserting portion 154 and the second holding unit 130, and the gasket 156 can be coiled on the part of the shaft 151 that is adjacent to the retaining portion 153 to decrease the effect of shocks between the retaining portion 153 and the second holding unit 130.

Similarly, the other end of the holding bar 111 and the other end of the holding bar 112 of the first holding unit 110 are positioned between one end of the holding bar 131 and one end of the holding bar 132 of another of the second holding units 130 that is positioned adjacent to the first holding unit 110, and the assembling holes 116 and 136 aligned to continue the assembly as before. These assembling operations are repeated, until all of the first holding units 110 and the second holding units 130 (or as many as are required in the particular situation) are alternately assembled one by one and enabled to rotate relative to each other by the rotation units 150.

Furthermore, in each of the two outermost holding units 110 and/or 130 of the reception apparatus 100, each of the holding bars 111, 112 and/or 131, 132 has one free or unattached end. In this embodiment, the shafts 151 of two of the rotation units 150 are respectively inserted in the assembling holes 116 and/or 136 defined in the unattached ends of the holding bars 111, 112 and/or 131, 132.

The lengths of the holding boards 113 and the lengths of the holding boards 133 being less than the lengths of the holding bars 111, 112/131, 132 which hold them, when the first holding units 110, the second holding units 130 and the rotation units 150 are assembled together, an assembling aperture 170 is created between each end of each of the holding boards 113 and the shaft 151 assembled adjacent to the end of the holding board 113, and an assembling aperture 190 is created between each end of each of the holding boards 133 and the shaft 151 assembled adjacent to the end of the holding board 133. The flexible cable unit 402 is positioned to repeatedly pass through selected ones of the assembling apertures 170, 190 and be wrapped around the shafts 151. Parts of the flexible cable unit 402 that are positioned between every two of the rotation units 150 are tightened on the holding boards 113, 133 to be flattened under tension. Thus, the cable connection units 410, 420 may each be connected to the ends of the flexible cable unit 402.

One of the two rotation units 150 respectively rotatably assembled on the two outermost ends of the reception apparatus 100 is fixed in the case 200 and adjacent to the circuit board 240, and the other is placed into the connection box 310 through the retaining groove 340 and is fixed in the connection box 310. The cable connection unit 410 is received in the connection box 310 and electrically connected to the main connectors 312. The cable connection unit 420 is electrically connected to the circuit board 240, and the electronic components of the electronic device are electrically connected to the main connector 312 through the flexible cable module 400. In this way, the electrical connection device 10 is assembled.

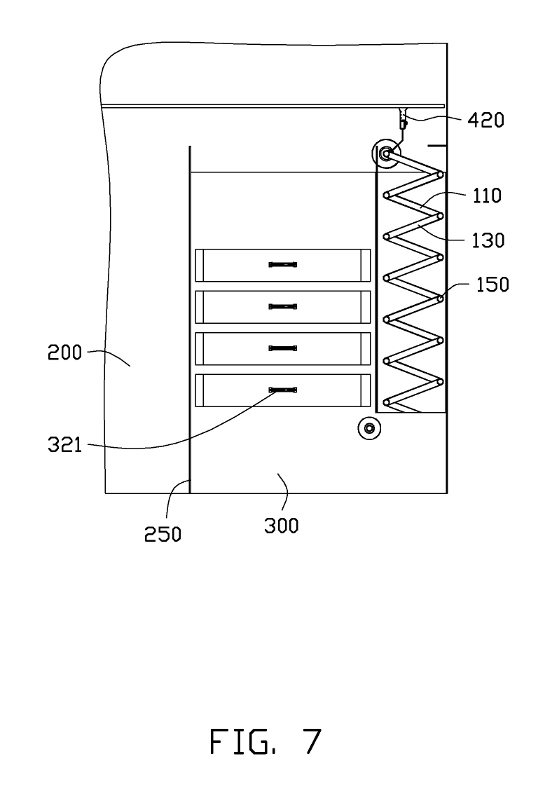

Also referring to FIG. 7, in use, the interface unit 300 is pushed into the reception space 230 to be received inside the case 200. When the connection box 310 slides towards the circuit board 240 along the sliding rails 250, the first holding units 110 and the second holding units 130 concertina, and thus the reception apparatus 100 and the flexible cable unit 402 are folded into a small space. The electronic components of the electronic device can be electrically connected to other electronic devices through the circuit board 240, the flexible cable unit 400, and the main connectors 312, and the accessories 323 can be electrically connected to other electronic devices through the subsidiary connectors 321 and the main connectors 312. Furthermore, the subsidiary connectors 321 can also be electrically connected to the cable connection unit 410 through the interface module 300, such that the accessories 323 can be electrically connected to the electronic components of the electronic device through the subsidiary connectors 321, the flexible cable unit 400, and the circuit board 240.

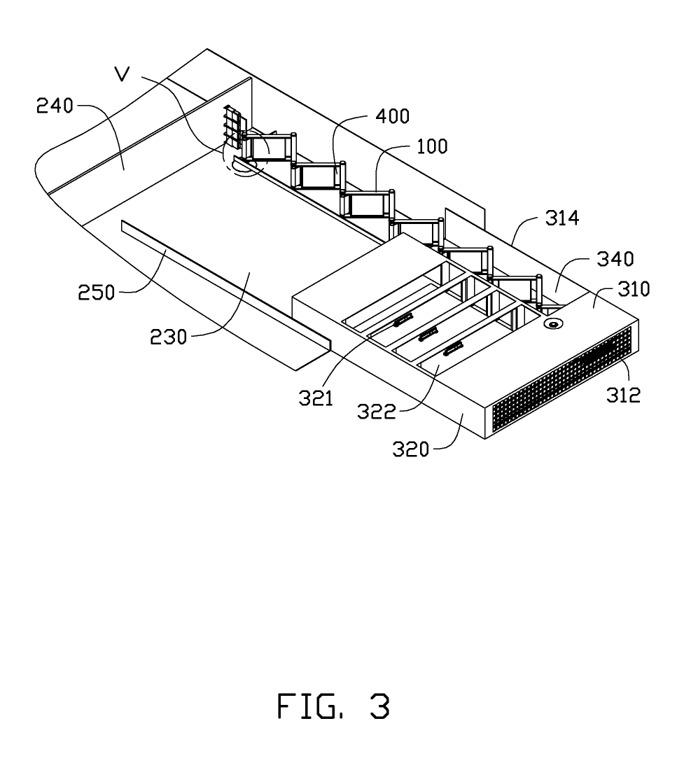

When the electrical connection device 10 needs to be repaired or the accessories 323 need to be changed, the interface module 300 is pulled out from the reception space 230. When the connection box 310 slides away from the circuit board 240 along the sliding rails 250, the first holding units 110 and the second holding units 130 unfold from each other (e.g., as shown in FIG. 3). In both the folded and the unfolded situations of the flexible cable unit 402, unwanted movements, unwanted lengths, and twisting or other deformation of the flexible cable unit 402 are limited by the reception apparatus 100. The flexible cable unit 402 can function in a neat and organized manner, and entanglements with other objects in the reception apparatus 100 are avoided. Any electromagnetic interference can be kept to a minimum, and the possibility of short-circuits is reduced.

In other embodiments, the flexible cable unit 402 can also be replaced by a single flexible cable or by a plurality of independent flexible cables, which are connected to the cable connection units 410, 420 and mounted on the reception apparatus 100 according to methods that are substantially similar to that of connecting the flexible cable unit 402 with the cable connection units 410, 420 and mounting the flexible cable unit 402 on the reception apparatus 100.

The first holding units 110 and the second holding units 130 can also be assembled together and enabled to rotate relative to each other by rivets (not shown) assembled in the assembling holes 116, 136, and thus the shafts 151 can be omitted. Correspondingly, the flexible cable unit 402 or a number of them may pass repeatedly through apertures formed between adjacent ones of the holding boards 113, 133, and parts of the flexible cable unit 402 can be kept in tight contact with the holding boards 113, 133 to be flattened.

The main connectors 312 and the subsidiary connectors 321 can be different kinds of electric connectors, such that the electric connection device 10 can electrically connect the electronic device with all types of accessories (e.g., the accessories 323).

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A reception apparatus for flexible cable modules, comprising:
a plurality of holding units, each of the holding units including two holding bars and a holding board; the two holding bars being parallel to each other, the holding board holding the two holding bars together lengthwise;
wherein the two holding bars of each of the holding units are rotatably assembled with the two holding bars of a next one of the holding units to rotatably assemble all of the holding units one by one, and wherein a length of each of the holding boards is less than lengths of the two holding bars held by the holding board such that assembling apertures are formed between adjacent ones of the holding boards, and the flexible cable modules repeatedly pass through selected ones of the assembling apertures to be held on the reception apparatus.

2. The reception apparatus as claimed in claim 1, wherein each of the holding bars defines assembling holes in both two ends of the holding bar.

3. The reception apparatus as claimed in claim 2, further comprising a plurality of rotation units, each of the rotation units including a shaft, and the shafts assembled in the assembling holes of the holding units to rotatably assemble the holding units one by one.

4. The reception apparatus as claimed in claim 3, wherein one of the shafts of the rotation units is assembled in two of the assembling holes respectively defined in the two holding bars of one of the holding units and two of the assembling holes respectively defined in the two holding bars of another of the holding units to assemble the two holding units together and enable the two holding units to rotate relative to each other.

5. The reception apparatus as claimed in claim 3, wherein one end of each of the shaft forms a disk-shaped retaining portion having an diameter that is greater than diameters of the assembling holes, the other end of the shaft forms a conic insertion portion, and a diameter of a part of the shaft that is adjacent to a bottom of the inserting portion decreases to define a limiting groove.

6. The reception apparatus as claimed in claim 5, wherein each of the rotation units further includes an elastic gasket and an elastic limiting member, the gasket coiled on a part of the shaft that is adjacent to the retaining portion and the limiting member engaging with the limiting groove.

7. The reception apparatus as claimed in claim 6, wherein the limiting member being substantially a hollow cone, an inner diameter of a top of the resilient member being less than a diameter of a bottom of the inserting portion, and an outer diameter of a bottom of the limiting member being greater than the diameters of the assembling holes.

8. The reception apparatus as claimed in claim 2, wherein the holding units includes a first kind of holding units and a second kind of holding units, a distance between the two holding bars of each of the second kind of holding units is greater than a width of each of the first kind of holding units; the first kind of holding units and the second kind of holding units assembled alternately, each of the two holding bars of each of the first kind of holding units having one end positioned between two ends of the two holding bars of one of the second kind of holding units assembled adjacent to the one of the first kind of holding units, and another end positioned between two ends of the two holding bars of the other of the second kind of holding units assembled adjacent to the same one of the first kind of holding units.

9. An electrical connection device for an electronic device, comprising:
a case including a circuit board;
an interface module slidably received in the case, the interface including a plurality of connectors;
a flexible cable module received in the case, the flexible cable module electrically connecting the circuit board with the connectors; and
a reception apparatus received in the case; the reception apparatus including a plurality of holding units, each of the holding units including two holding bars and a holding board; the two holding bars being parallel to each other, the holding board holding the two holding bars together lengthwise; wherein the two holding bars of each of the holding units are rotatably assembled with the two holding bars of a next one of the holding units to rotatably assemble all of the holding units one by one, and wherein a length of each of the holding boards is less than lengths of the two holding bars held by the holding board such that assembling apertures are formed between adjacent ones of the holding boards, and the flexible cable module repeatedly passes through selected ones of the assembling apertures to be held on the reception apparatus.

10. The electrical connection device as claimed in claim 9, wherein parts of the flexible cable module are kept in tight contact with the holding boards to be flattened.

11. The electrical connection device as claimed in claim 9, wherein when the interface module slides inward the case, the holding units are driven to rotate relative to each other and fold the reception apparatus and the flexible cable unit; when the interface module slides outward the case, the holding units are driven to rotate relative to each other and unfold the reception apparatus and the flexible cable unit.

12. The electrical connection device as claimed in claim 9, wherein each of the holding bars defines assembling holes in both two ends of the holding bar.

13. The electrical connection device as claimed in claim 12, further comprising a plurality of rotation units, each of the rotation units including a shaft, and the shafts assembled in the assembling holes of the holding units to rotatably assemble the holding units one by one.

14. The electrical connection device as claimed in claim 13, wherein one of the shafts of the rotation units is assembled in two of the assembling holes respectively defined in the two holding bars of one of the holding units and two of the assembling holes respectively defined in the two holding bars of another of the holding units to assemble the two holding units together and enable the two holding units to rotate relative to each other.

15. The electrical connection device as claimed in claim 13, wherein the shafts of two of the rotation units are respectively assembled in the assembling holes defined in the ends of the holding bars of two outermost ones of the holding units that are not assembled with any other of the holding units, thereby respectively rotatably assembling the two rotation unit on two outermost ends of the reception apparatus; one of the two rotation units respectively rotatably assembled on the two outermost ends of the reception apparatus fixed in the case and adjacent to the circuit board, and the other fixed in the interface module.

16. The electrical connection device as claimed in claim 12, wherein the holding units includes a first kind of holding units and a second kind of holding units, a distance between the two holding bars of each of the second kind of holding units is greater than a width of each of the first kind of holding units; the first kind of holding units and the second kind of holding units assembled alternately, each of the two holding bars of each of the first kind of holding units having one end positioned between two ends of the two holding bars of one of the second kind of holding units assembled adjacent to the one of the first kind of holding units, and another end positioned between two ends of the two holding bars of the other of the second kind of holding units assembled adjacent to the same one of the first kind of holding units.
